(19) United States
(12) Patent Application Publication
(10) Pub. No.: US 2013/0120927 A1
(43) Pub. Date: May 16, 2013

(54) EXTRACTABLE STORAGE APPARATUS FOR ELECTRONIC DEVICES AND ELECTRONIC EQUIPMENT THEREWITH

(71) Applicants: Hsuan-Ying Wen, New Taipei City (TW); Fu-Jen Yang, New Taipei City (TW)

(72) Inventors: Hsuan-Ying Wen, New Taipei City (TW); Fu-Jen Yang, New Taipei City (TW)

(21) Appl. No.: 13/425,424

(22) Filed: Mar. 21, 2012

(30) Foreign Application Priority Data
Nov. 11, 2011 (TW) 100221259

(51) Int. Cl. G06F 1/16; H05K 7/00

(52) U.S. Cl. 361/679.39; 361/679.01; 361/748

(57) ABSTRACT

An extractable storage apparatus for electronic devices and electronic equipment therewith are disclosed. The electronic equipment includes an equipment frame, a signal processing apparatus, a plurality of electronic devices, and the extractable storage apparatus. The signal processing apparatus and the extractable storage apparatus are disposed on the equipment frame. The extractable storage apparatus includes a casing, a bracket, and a power connection mechanism. The bracket is disposed in an accommodating space of the casing in an extractable way and includes a plurality of storage slots to accommodate the electronic devices. The power connection mechanism is disposed in the casing and is electrically connected to the electronic devices to supply power to the electronic devices. When the bracket is extracted out the casing, the power connection mechanism keeps powering the electronic devices, which is convenient for a user to perform a hot-plug operation on one of the electronic devices.

### BACKGROUND OF THE INVENTION

1. Field of the Invention

The invention relates to an extractable storage apparatus and electronic equipment, and especially relates to an extractable storage apparatus, capable of keeping being electrically connected to electronic devices accommodated therein during an extraction operation, and electronic equipment with the extractable storage apparatus.

2. Description of the Prior Art

In the architecture of a conventional computer, desktop computer for example, head disks are mounted inside the casing of the computer in advance. The space of the casing is limited, so the disposition quantity of the hard disks is therefore limited. As computer application such as server application develops, one or few hard disks cannot meet the requirement for the server application. So a computer-based equipment architecture accommodating more hard disks has been developed. In practice, the computer-based equipment is installed in an equipment frame for convenient management. For quick maintenance of the hard disks or conveniently performing hot-plug operation on the hard disks, the hard disks are usually disposed at the front panel of the computer-based equipment for users' convenience to extract out or insert it. The area of the panel is limited, so the allowable quantity of the hard disks to be disposed is limited. If the hard disks are to be disposed in a way of efficiently using the space of the equipment casing, the user may need to go around to the back of the equipment frame or to extract the computer-based equipment from the equipment frame, even to open the equipment casing of the computer-based equipment, so that the user can change the hard disks. It is very inconvenient. In addition, in blade server architecture, boards can be disposed fixedly or be disposed on a movable bracket to be connected to a bottom plate. When one of the boards needs to be exchanged, the bracket needs to be extracted first. However, when the bracket is extracted, the boards on the bracket are disengaged from the bottom plate, leading to system halt, which is disadvantageous to the whole system operation.

### SUMMARY OF THE INVENTION

An aspect of the invention is to provide an extractable storage apparatus for electronic devices. The extractable storage apparatus uses an extractable bracket so as to keep powering electronic devices accommodated therein when the bracket is extracted for changing one or more electronic devices by a user.

The extractable storage apparatus according to one embodiment of the invention includes a casing, a bracket, and a power connection mechanism. The casing has an accommodating space and an opening communicating with the accommodating space. The bracket is disposed in the accommodating space through the opening in an extractable way and has a plurality of storage slots. Each storage slot is capable of accommodating at least one electronic device. The power connection mechanism is disposed in the casing and electrically connected to the electronic devices to supply power to the electronic devices. When the bracket is extracted out the casing from the opening, the power connection mechanism keeps powering the electronic devices. Thereby, a user can easily change one of the electronic devices by use of the extractable bracket; at the same time, the other electronic devices accommodated in the storage slots can be still powered continuously.

Another aspect of the invention is to provide electronic equipment. The electronic equipment includes an equipment frame, a plurality of electronic devices, a signal processing apparatus, and an extractable storage apparatus. The signal processing apparatus is disposed on the equipment frame and is connected in communication to the electronic devices. The extractable storage apparatus is disposed on the equipment frame and accommodates the electronic devices. The extractable storage apparatus includes a casing, a bracket, and a power connection mechanism. The casing has an accommodating space and an opening communicating with the accommodating space. The bracket is disposed in the accommodating space through the opening in an extractable way and has a plurality of storage slots. Each storage slot is capable of accommodating at least one of the electronic devices. The power connection mechanism is disposed in the casing and electrically connected to the electronic devices to supply power to the electronic devices. When the bracket is extracted out the casing from the opening, the power connection mechanism keeps powering the electronic devices. Similarly, a user can easily change one of the electronic devices by use of the extractable bracket; at the same time, the other electronic devices accommodated in the storage slots can be still powered continuously, so that the electronic equipment of the invention still can work normally during changing operation.

These and other objectives of the invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a schematic diagram illustrating electronic equipment of a preferred embodiment according to the invention.

FIG. 2 is a schematic diagram illustrating an extractable storage apparatus of the electronic equipment in FIG. 1.

FIG. 3 is a schematic diagram illustrating the extractable storage apparatus in FIG. 2 which has been extracted.

FIG. 4 is an exploded view of apart of the extractable storage apparatus in FIG. 2.

FIG. 5 is an action diagram of a flexible signal connecting member of the extractable storage apparatus in FIG. 3.

FIG. 6 is an action diagram of a flexible power connecting member of the extractable storage apparatus in FIG. 3.

FIG. 7 is an action diagram of the extractable storage apparatus with spiral cables according to an embodiment.

FIG. 8 is a top view of a part of a bracket of the extractable storage apparatus in FIG. 3.

FIG. 9 is a top view of the internal structure of the extractable storage apparatus according to another embodiment.

### DETAILED DESCRIPTION

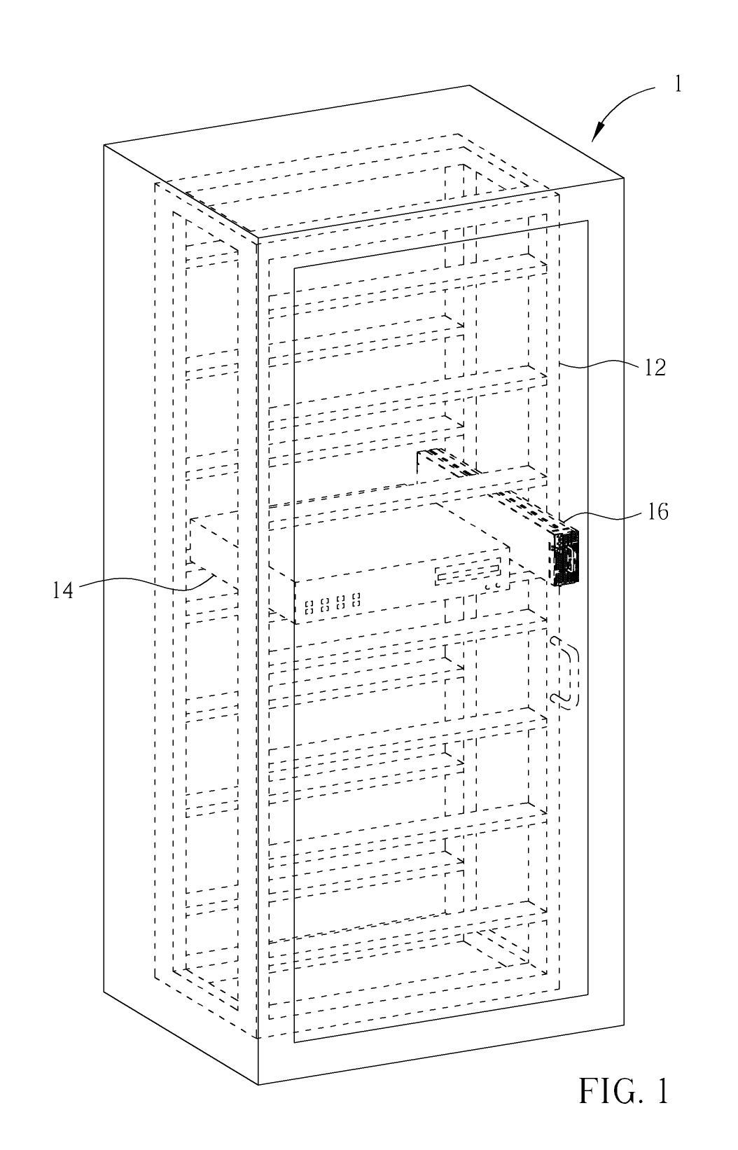

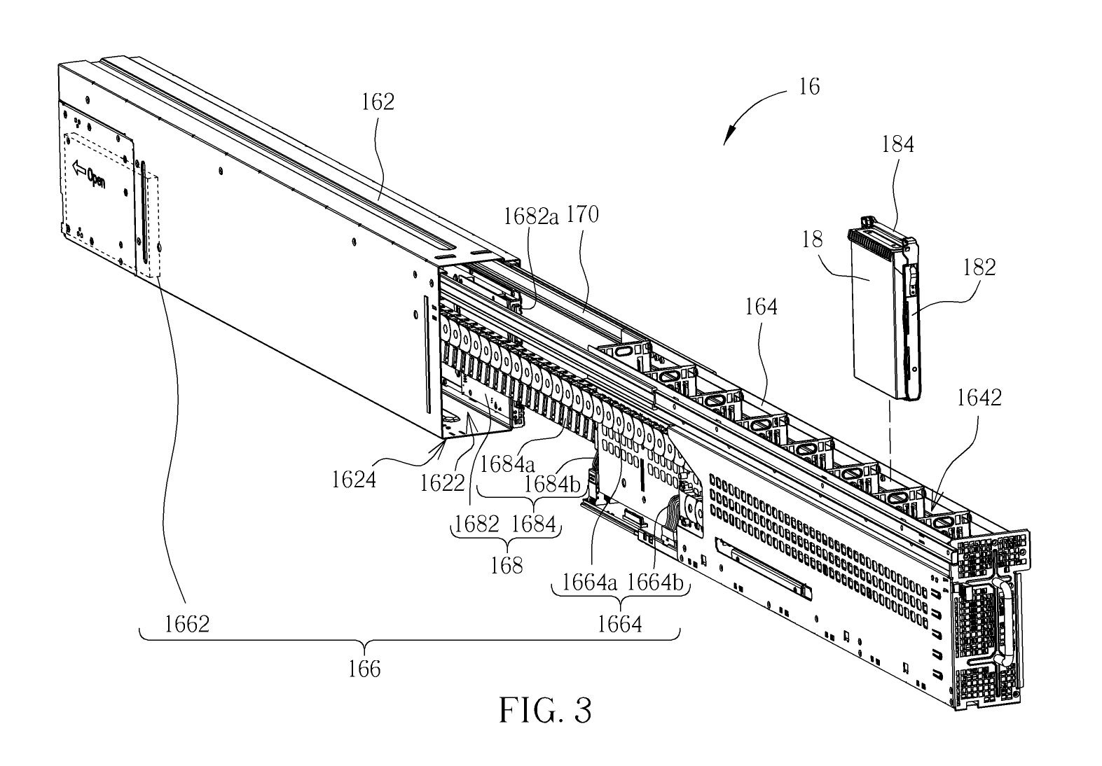

Please refer to FIG. 1, which is a schematic diagram illustrating a schematic diagram illustrating electronic equipment 1 according to one embodiment of the invention. The electronic equipment 1 includes an equipment frame 12, a signal processing apparatus 14, an extractable storage apparatus 16. The signal processing apparatus 14 and the extractable storage apparatus 16 are disposed on the equipment frame 12. The extractable storage apparatus 16 accommodates a plurality of electronic devices 18 (referring to FIG. 3) and provide power supply to the electronic devices 18. The signal processing apparatus 14 and the electronic devices 18 are connected in communication. When the extractable storage apparatus 16 is extracted, the extractable storage apparatus 16 still can keep powering the electronic devices 18. In the embodiment, the signal processing apparatus 14 can be a server host; the electronic devices 18 can be hard disks or other electronic devices. However, the invention is not limited thereto. In principle, any electronic device which needs electricity for operation is applicable to be accommodated in the extractable storage apparatus of the invention.

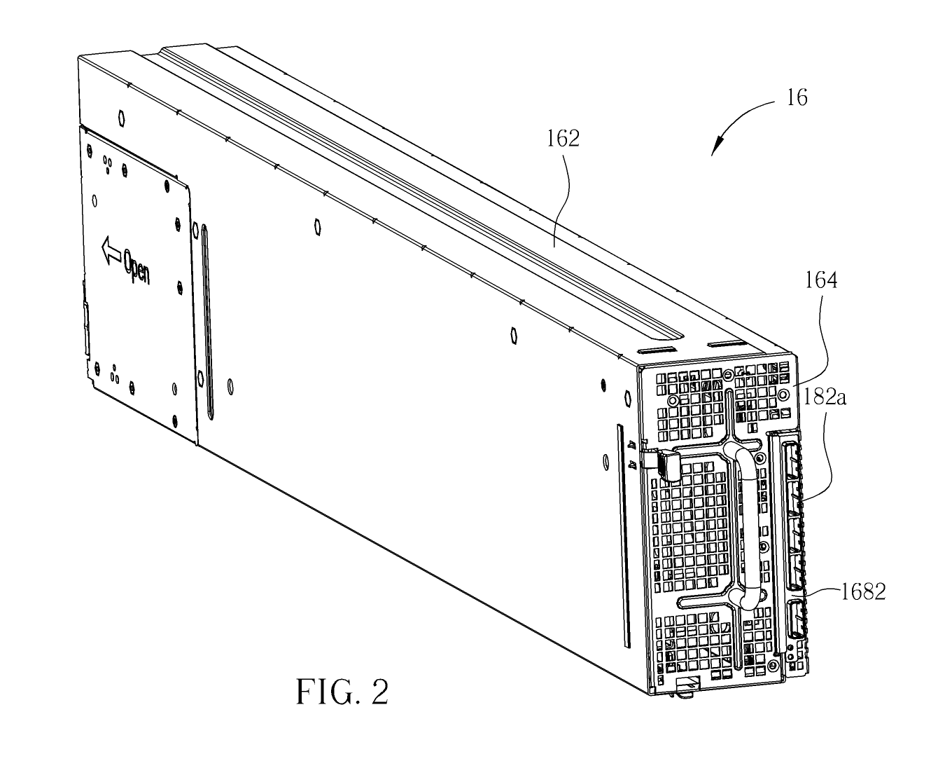

Please refer to FIG. 2 and FIG. 3. FIG. 2 is a schematic diagram illustrating the extractable storage apparatus 16. FIG. 3 is a schematic diagram illustrating the extractable storage apparatus 16 having been extracted. The extractable storage apparatus 16 includes a casing 162, a bracket 164, a power connection mechanism 166, a signal connection mechanism 168, and a slide mechanism 170. The casing 162 has an accommodating space 1622 and an opening 1624 communicating with the accommodating space 1622. The slide mechanism 170 is connected to the casing 162 and the bracket 164. Thereby, the bracket 164 can be disposed in the accommodating space 1622 through the opening 1624 in an extractable way; that is, the bracket 164 can slide in or out the accommodating space 1622 relative to the casing 162 by use of the slide mechanism 170. In practice, the structure of the slide mechanism 170 is not limited to the embodiment, and the slide mechanism 170 is not limited to be disposed at the upper portion of the bracket 164. Furthermore, the invention is also applied to an extractable storage apparatus without the slide mechanism. For example, the sliding of the bracket 164 in the accommodating space 1622 can be supported by the structure of the bracket 164. The bracket 164 has a plurality of storage slots 1642. Each storage slot 1642 accommodates at least one electronic device 18. For simple drawings, only one electronic device 18 is shown in FIG. 3.

The power connection mechanism 166 is disposed in the casing 162 and electrically connected to the electronic devices 18 to power the electronic devices 18. The power connection mechanism 166 includes a power conversion device 1662 and a flexible power connecting member 1664. The power conversion device 1662 is disposed in the casing 162 (the position thereof is shown by dashed lines in FIG. 3) for being electrically connected to an external power source (such as market power) and converting the power, for example from alternating current to direct current for the electronic devices 18. The flexible power connecting member 1664 electrically connects the power conversion device 1662 with the electronic devices 18. In the embodiment, the power conversion device 1662 is disposed in an end portion of the casing 162 opposite to the opening 1624, so as to be conducive to electrical connection with the external power source and cable management. The flexible power connecting member 1664 includes a cable chain 1664a and a power cable 1664b disposed in the cable chain 1664a. The two ends of the cable chain 1664a are fixed on the power conversion device 1662 and the bracket 164 respectively, so that the power cable 1664b can be protected effectively from being pulled excessively.

The signal connection mechanism 168 is disposed in the casing 162 and connected in communication to the electronic devices 18 and the signal processing apparatus 14. The signal connection mechanism 168 includes a signal conversion device 1682 and a flexible signal connecting member 1684. The signal conversion device 1682 is disposed in the casing 162 and is connected in communication to the signal processing apparatus 14. The flexible signal connecting member 1684 electrically connects the signal conversion device 1682 and the electronic devices 18. In the embodiment, the signal conversion device 1682 is exposed through the opening 1624. The signal processing apparatus 14 is electrically connected to the signal conversion device 1682 through a connection port 1682a of the signal conversion device 1682. The flexible signal connecting member 1684 includes two cable chains 1684a arranged side by side and two signal cables 1684b disposed in the two cable chains 1684a respectively. The two ends of each cable chain 1684a are fixed on the signal conversion device 1682 and the bracket 164 respectively, so that the signal cables 1684b can be protected effectively from being pulled excessively.

Therefore, when the bracket 164 is extracted out the casing 162 from the opening 1624, the power cable 1664b of the power connection mechanism 166 can keep being electrically connected to the electronic devices 18, and the signal cable 1684b of the signal connection mechanism 168 also can keep being electrically connected to the electronic devices 18, so that the power connection mechanism 166 can keep powering the electronic devices 18 and the signal processing apparatus 14 can keep communicating with the electronic devices 18 through the signal connection mechanism 168. In other words, when a user needs to extract the bracket 164 for viewing or changing the electronic devices 18, the electronic devices 18 still can work normally before taken out the storage slots 1642, and the electronic equipment 1 also can keep providing service. It solves the problem that once a conventional bracket is extracted out, the electronic devices thereon such as system boards are not powered.

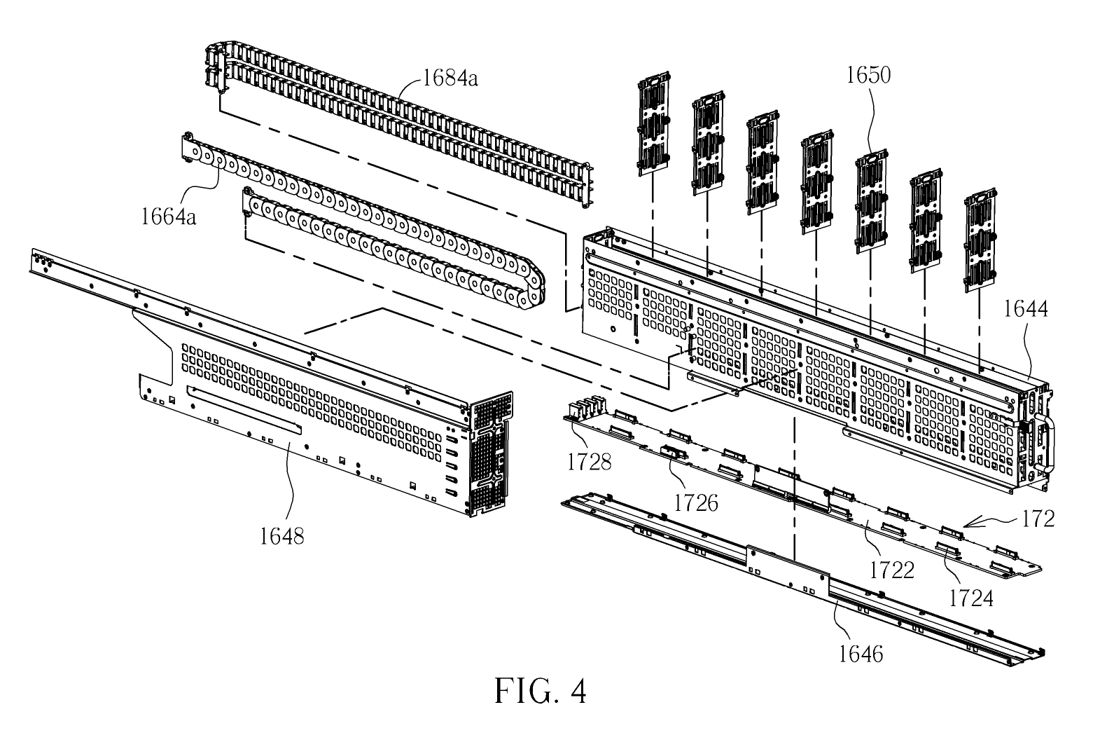

Please refer to FIG. 4, which is an exploded view of a part of the extractable storage apparatus 16. The bracket 164 includes a rectangle frame 1644, a bottom plate 1646, a side protection plate 1648, and a plurality of division plates 1650. The division plates 1650 are inserted into the rectangle frame 1644 for forming the storage slots 1642. In the embodiment, the extractable storage apparatus 16 includes a connection circuit board module 172 disposed in the bracket 164 on the bottom plate 1646 to integrate the power and single connection of the electronic devices 18. The connection circuit board module 172 includes a circuit board 1722, a plurality of device connectors 1724, a power connector 1726, and a plurality of transmission connectors 1728. The device connector 1724 is located at the bottom of the storage slot 1642 such that the electronic device 18 can be engaged to the device connector 1724 after inserted into the storage slot 1642. The flexible signal connecting member 1684 is engaged to the transmission connector 1728 of the connection circuit board module 172 by fixing one end of the cable chain 1684a on the bracket 164. The flexible signal connecting member 1684 and the electronic devices 18 are therefore electrically connected. The flexible power connecting member 1664 is engaged to the power connector 1726 of the connection circuit board module 172 by fixing one end of the cable chain 1664a on the bracket 164. The flexible power connecting member 1664 and the electronic devices 18 are therefore electrically connected for powering. It is added that in practice, the connection circuit board module 172 can be designed to allow hot-plug operation on the electronic devices 18 for users.

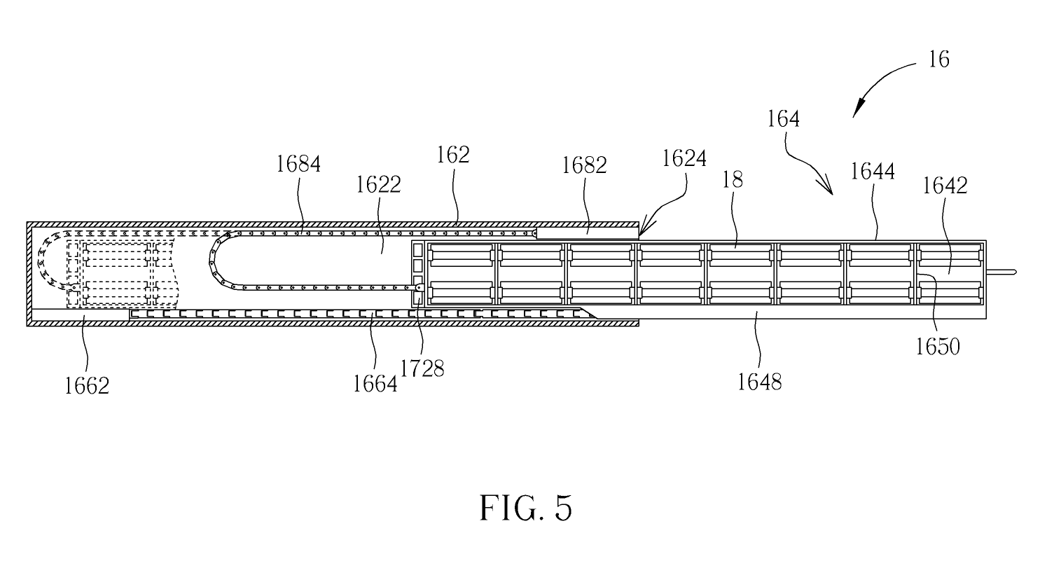

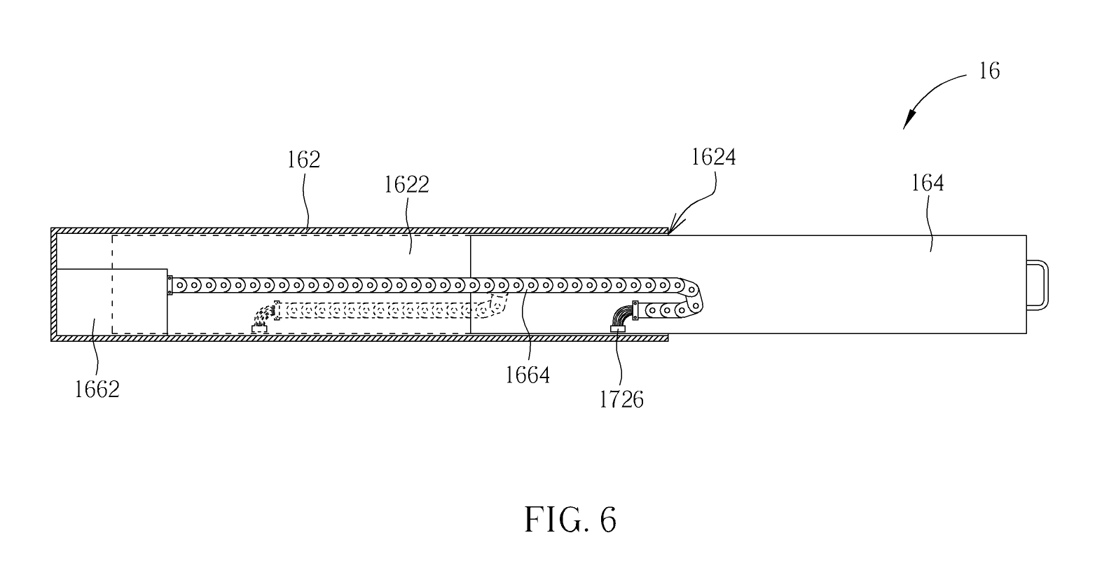

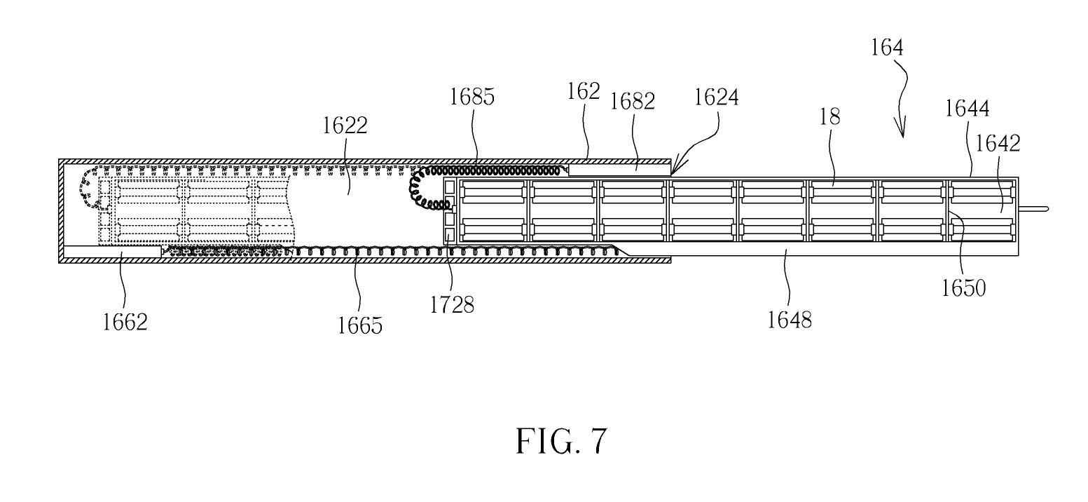

Please refer to FIG. 5, which is an action diagram of the flexible signal connecting member 1684. Because the transmission connectors 1728 move relative to the signal conversion device 1682 when the bracket 164 moves, the embodiment use the flexible signal connecting member 1684 of chain type to connect the transmission connectors 1728 with the signal conversion device 1682 so that the signal conversion device 1682 and the electronic devices 18 can keep being electrically connected during the movement of the bracket 164. Please refer to FIG. 6, which is an action diagram of the flexible power connecting member 1664. Similarly, the embodiment use the flexible power connecting member 1664 of chain type to connect the power connector 1726 with the power conversion device 1662 so that the power conversion device 1662 and the electronic devices 18 can keep being electrically connected during the movement of the bracket 164. In the embodiment, the flexible signal connecting member 1684 and the flexible power connecting member 1664 are realized by members with chain structure so as to obtain flexible connections, but the invention is not limited thereto. For example, a spiral cable can be used to perform the flexible connection; the component quantity is therefore decreased. As shown in FIG. 7, the flexible signal connecting member 1685 and the flexible power connecting member 1665 are realized by spiral cables. The flexible connections can be performed by use of the elasticity of the spiral structure of the spiral cables.

It is added that in the above embodiments, the signal connection mechanism 168 is connected in communication by physical cables to the signal processing apparatus 14 and the electronic devices 18, but the invention is not limited thereto. For example, the signal connection mechanism 168 can be connected in communication by a wireless communication way to the signal processing apparatus 14 and the electronic devices 18; in this case, the design of the disposition for the signal conversion device 1682 also can be more flexible. Similarly, the signal connection mechanism 168 can be connected by a wireless communication way to the connection circuit board module 172 so as to obtain the communication connection with the electronic devices 18. In addition, in the above embodiments, the power connection mechanism 166 and the connection circuit board module 172 are connected in an invariable way; however, the invention is not limited thereto. For example, a fixed slide disposed inside the casing 162 and electrified by the power conversion device 1662 while metal springs disposed on the bracket 164 and electrically connected to the connection circuit board module 172. By use of the metal springs continuously and elastically contacting the electrified slide, the connection circuit board module 172 can keep being powered during the movement of the bracket 164 relative to the casing 162.

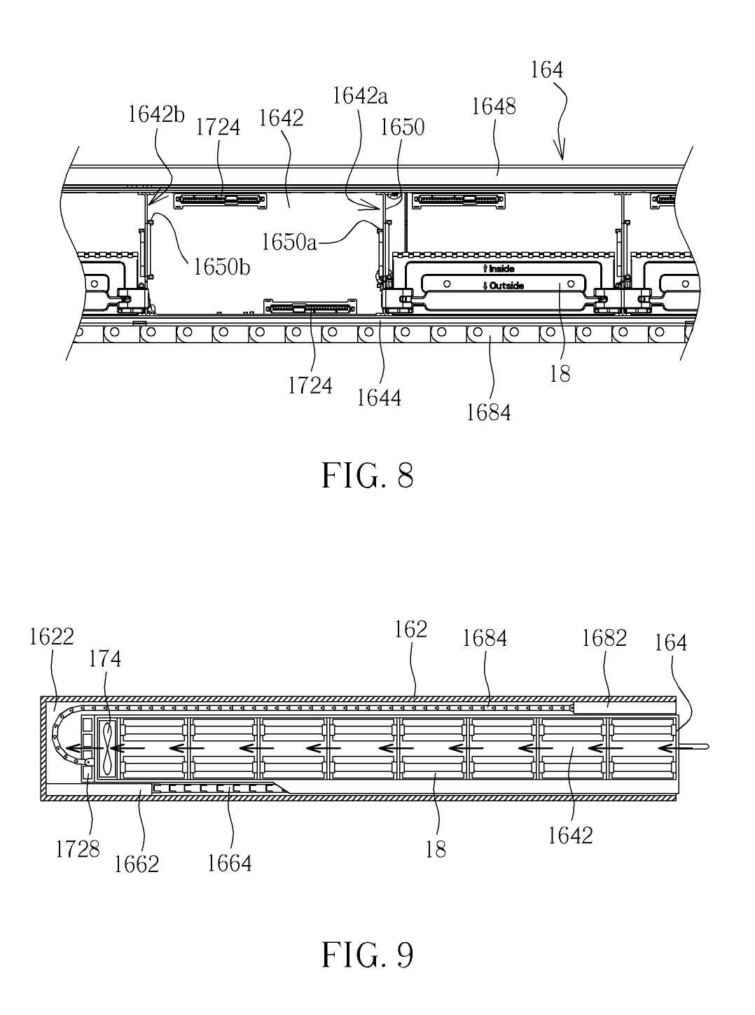

Please refer to FIG. 2, FIG. 3, and FIG. 8. FIG. 8 is a top view of a part of the bracket 164. In the embodiment, the division plates 1650 thereon form rib structures 1650a and 1650b inside each storage slot 1642, so as to form slides 1642a and 1642b. The electronic device 18 includes a slider 182 at its side. The electronic device 18 slide into the storage slot 1642 by sliding the slider 182 into the slide 1642a or 1642b. When a user needs to extract the electronic device 18, the user can directly pull a handle 184 to extract the electronic device 18 out the storage slot 1642. In practice, the electronic device 18 can include a hard disk and an extractable structure thereon forming the slider 182 and the handle 184, or the slider 182 and the handle 184 respectively are fixed directly on the hard disk so as to perform the abovementioned sliding movement. It is added that even only one side of the storage slot 1642 thereon disposes the slide, and the electronic device 18 still can be effectively guided to slide into the storage slot 1642 to be engaged to the device connector 1724 precisely. Furthermore, in practice, the quantity of the electronic devices 18 accommodated in each storage slot 1642 depends on the product design. It is not limited to two as disclosed above.

Please refer to FIG. 9, which is a top view of the internal structure of the extractable storage apparatus according to another embodiment. The bracket 164 thereon disposes an airflow guiding device 174 such as a fan. Many holes are formed on the bracket 164, so the airflow guiding device 174 guides airflow outside the extractable storage apparatus to pass through the storage slots 1642 for dissipating heat by the electronic devices 18. The path of the airflow is shown by arrows in FIG. 9. In practice, the disposition of the airflow guiding device 174 is not limited to the end portion of the bracket 164; therefore, the airflow guiding device 174 can be disposed at any place within the airflow path, for example at the entry for the airflow or the middle portion of the bracket 164. Furthermore, the airflow guiding device 174 can be fixed on the casing 162, which also can dissipate heat by the electronic devices 18 and other components disposed in the casing 162.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An extractable storage apparatus for electronic devices, the extractable storage apparatus comprising:
a casing having an accommodating space and an opening communicating with the accommodating space;
a bracket disposed in the accommodating space through the opening in an extractable way and having a plurality of storage slots, each storage slot being capable of accommodating at least one electronic device; and
a power connection mechanism disposed in the casing and electrically connected to the electronic device to supply power to the electronic device, wherein when the bracket is extracted out the casing from the opening, the power connection mechanism keeps powering the electronic device.

2. The extractable storage apparatus of claim 1, wherein the power connection mechanism comprises a power conversion device and a flexible power connecting member, the power conversion device is disposed in the casing for being electrically connected to an external power source, and the flexible power connecting member electrically connects the power conversion device and the electronic device.

3. The extractable storage apparatus of claim 2, wherein the flexible power connecting member is a spiral cable.

4. The extractable storage apparatus of claim 2, wherein the flexible power connecting member comprises a cable chain and a power cable disposed in the cable chain, and the cable chain connects the power conversion device and the bracket.

5. The extractable storage apparatus of claim 4, further comprising a signal conversion device and a signal cable, the signal conversion device being disposed in the casing for being connected in communication to an external signal processing apparatus, wherein the signal cable is disposed in the cable chain and electrically connects the signal conversion device and the electronic device, and when the bracket is extracted out the casing from the opening, the signal cable keeps being connected to the electronic device.

6. The extractable storage apparatus of claim 2, further comprising a connection circuit board module disposed in the bracket for being electrically connected to the electronic device, wherein the flexible power connecting member is electrically connected to the connection circuit board module so as to be being electrically connected to the electronic device through the connection circuit board module.

7. The extractable storage apparatus of claim 2, wherein the power conversion device is disposed in an end portion of the casing opposite to the opening.

8. The extractable storage apparatus of claim 1, further comprising a signal connection mechanism disposed in the casing for being connected in communication to the electronic device, wherein when the bracket is extracted out the casing from the opening, the signal connection mechanism keeps being connected in communication to the electronic device.

9. The extractable storage apparatus of claim 8, wherein the signal connection mechanism comprises a signal conversion device and a flexible signal connecting member, the signal conversion device is disposed in the casing for being connected in communication to an external signal processing apparatus, and the flexible signal connecting member electrically connects the signal conversion device and the electronic device.

10. The extractable storage apparatus of claim 9, wherein the flexible signal connecting member is a spiral cable.

11. The extractable storage apparatus of claim 9, wherein the flexible signal connecting member comprises a cable chain and a signal cable disposed in the cable chain, and the cable chain connects the signal conversion device and the bracket.

12. The extractable storage apparatus of claim 9, further comprising a connection circuit board module disposed in the bracket for being electrically connected to the electronic device, wherein the flexible signal connecting member is electrically connected to the connection circuit board module so as to be electrically connected to the electronic device through the connection circuit board module.

13. The extractable storage apparatus of claim 9, wherein the signal conversion device is disposed adjacent to the opening.

14. The extractable storage apparatus of claim 1, further comprising a slide mechanism connected to the casing and the bracket, wherein the bracket is capable of sliding in or sliding out the accommodating space relative to the casing by use of the slide mechanism.

15. An electronic equipment with extractable storage apparatus, the electronic equipment comprising:
an equipment frame;
a plurality of electronic devices;
a signal processing apparatus disposed on the equipment frame and connected in communication to the electronic devices; and
an extractable storage apparatus disposed on the equipment frame and accommodating the electronic devices, the extractable storage apparatus comprising:
a casing having an accommodating space and an opening communicating with the accommodating space;
a bracket disposed in the accommodating space through the opening in an extractable way and having a plurality of storage slots, each storage slot being capable of accommodating at least one of the electronic devices; and
a power connection mechanism disposed in the casing and electrically connected to the electronic devices to supply power to the electronic devices, wherein when the bracket is extracted out the casing from the opening, the power connection mechanism keeps powering the electronic devices.

16. The electronic equipment of claim 15, wherein the power connection mechanism comprises a power conversion device and a flexible power connecting member, the power conversion device is disposed in the casing for being electrically connected to an external power source, and the flexible power connecting member electrically connects the power conversion device and the electronic devices.

17. The electronic equipment of claim 16, wherein the flexible power connecting member comprises a cable chain and a power cable disposed in the cable chain, the cable chain connects the power conversion device and the bracket, the extractable storage apparatus comprises a signal conversion device and a signal cable, the signal conversion device is disposed in the casing and is connected in communication to the signal processing apparatus, the signal cable is disposed in the cable chain and electrically connects the signal conversion device and the electronic devices, and when the bracket is extracted out the casing from the opening, the signal cable keeps being connected to the electronic devices.

18. The electronic equipment of claim 16, wherein the extractable storage apparatus comprises a connection circuit board module disposed in the bracket and electrically connected to the electronic devices, and the flexible power connecting member is electrically connected to the connection circuit board module so as to be being electrically connected to the electronic devices through the connection circuit board module.

19. The electronic equipment of claim 16, wherein the power conversion device is disposed in an end portion of the casing opposite to the opening.

20. The electronic equipment of claim 15, wherein the extractable storage apparatus comprises a signal connection mechanism disposed in the casing, the signal connection mechanism is connected in communication to the electronic devices and the signal processing apparatus, and when the bracket is extracted out the casing from the opening, the signal connection mechanism keeps being connected in communication to the electronic devices.

21. The electronic equipment of claim 20, wherein the signal connection mechanism comprises a signal conversion device and a flexible signal connecting member, the signal conversion device is disposed in the casing and is connected in communication to the signal processing apparatus, the flexible signal connecting member electrically connects the signal conversion device and the electronic devices, the flexible signal connecting member comprises a cable chain and a signal cable disposed in the cable chain, the cable chain connects the signal conversion device and the bracket, the extractable storage apparatus comprises a connection circuit board module disposed in the bracket and electrically connected to the electronic devices, and the flexible signal connecting member is electrically connected to the connection circuit board module so as to be electrically connected to the electronic devices through the connection circuit board module.

22. The electronic equipment of claim 15, wherein the extractable storage apparatus comprises a slide mechanism connected to the casing and the bracket, and the bracket is capable of sliding in or sliding out the accommodating space relative to the casing by use of the slide mechanism.

23. The electronic equipment of claim 15, wherein at least one slide is disposed in each storage slot, the electronic device comprises a slider at a side of the electronic device, and the electronic device slides in the storage slot by sliding the slider in the slide.

24. The electronic equipment of claim 23, wherein the electronic device is a hard disk.

25. The electronic equipment of claim 23, wherein the extractable storage apparatus comprises a signal connection mechanism and a connection circuit board module, the signal connection mechanism is disposed in the casing so as to be connected in communication to the electronic devices and the signal processing apparatus, the connection circuit board module is disposed in the bracket and is electrically connected to the electronic devices, and the power connection mechanism and the signal connection mechanism are electrically connected to the electronic devices through the connection circuit board module so as to provide hot-plug operation on the electronic devices.
